(19) United States
(12) Patent Application Publication
(10) Pub. No.: US 2007/0158706 A1
(43) Pub. Date: Jul. 12, 2007

(54) THIN FILM TRANSISTOR

(76) Inventors: Chih-Ming Lai, Changhua County (TW); Yung-Hui Yeh, Hsinchu City (TW); Yi-Hsun Huang, Tainan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,147

(22) Filed: Mar. 8, 2006

(30) Foreign Application Priority Data
Dec. 30, 2005 (TW) 94147517

(51) Int. Cl. H01L 31/113; H01L 31/062

(52) U.S. Cl. 257/290

(57) ABSTRACT

A thin film transistor for fabricating on a flexible substrate is provided. The thin film transistor includes a gate, a gate insulating layer, a channel layer, a first conductive pattern, and a second conductive pattern. The gate and the gate insulating layer are disposed on the flexible substrate, and the gate insulating layer covers the gate. The channel layer is disposed on the gate insulating layer and located above the gate. The channel layer has a first contact region and multiple second contact regions, wherein the first contact region is located between the second contact regions. In addition, the first conductive pattern is disposed on a portion of the gate insulating layer and the first contact region; and the second conductive pattern electrically insulated from the first conductive pattern is disposed on a portion of the gate insulating layer and the second contact region.

### CROSS-REFERENCE TO RELATED APPLICATION

This application claims the priority benefit of Taiwan application serial no. 94147517, filed on Dec. 30, 2005. All disclosure of the Taiwan application is incorporated herein by reference.

### BACKGROUND OF THE INVENTION

1. Field of Invention

The present invention relates to a thin film transistor, and more particularly, to a thin film transistor suitable for being fabricated over a flexible substrate.

2. Description of Related Art

To meet the lifestyle of modern people, the volume of display has gradually become thinner and thinner. Although the conventional Cathode Ray Tube (CRT) display has its own advantages, the CRT display is large in size and occupies too much space due to the internal electronic chamber structure, and when the CRT display outputs images, human eyes will be hurt by the generated radiation. Therefore, the Flat Panel Display (FPD), such as Plasma Display Panel (PDP), Liquid Crystal Display (LCD), Organic Electro-Luminescence (OEL) Display, and Electronic-ink (E-ink) Display developed through integrating opto-electronic technique with the semiconductor manufacturing technique has gradually become the mainstream of display products.

Generally, whether or not the FPD is flexible depends on the substrate materials. When the substrate that the FPD uses is a rigid substrate (e.g., glass substrate), the FPD is not flexible almost. Otherwise, when the substrate that the FPD uses is a flexible substrate (e.g., plastic substrate), the FPD is quite flexible. Recently, the technique of fabricating thin film transistors over a rigid substrate has become mature, but the technique of fabricating thin film transistors over a flexible substrate is still under development. In particular, since the thermal expansion coefficient of the flexible substrate is very high, after the thin film deposition process (high temperature process), the photolithography process, and the etching process are performed on the flexible substrate, serious misalignment will occur between different thin films, resulting in the failure of the thin film transistors.

FIG. 1 is a schematic view of the layout of a conventional thin film transistor. Referring to FIG. 1, a conventional thin film transistor 100 is usually fabricated over a substrate (not shown), and the thin film transistor 100 includes a gate 102, a gate insulating layer 104, a channel layer 106, a source 108, and a drain 110. The gate 102 is disposed on the substrate, and the gate insulating layer 104 is disposed over the substrate for covering the gate 102. The channel layer 106 is located above the gate 102. In other words, the gate insulating layer 104 is located between the gate 102 and the channel layer 106. Further, the source 108 and the drain 110 are disposed on a portion of the gate insulating layer 104 and cover a portion of the channel layer 106.

When the substrate employed is a substrate with a high thermal expansion coefficient, an offset between the gate 102 and other thin films will occur. As shown by the dashed lines in FIG. 1, when misalignment occur between the gate 102 and the source 108 and the drain 110, the source 108 cannot cover the channel layer 106, that is, the film transistor 100 cannot operate normally. It can be seen clearly from FIG. 1 that, the misalignment tolerance of the layout of the thin film transistor 100 in the X-axis direction and the Y-axis direction is not desirable, such that when the thin film transistor 100 is manufactured on the flexible substrate, the manufacturing yield cannot be enhanced effectively.

In order to enhance the manufacturing yield of the thin film transistor on the flexible substrate, skilled artisans in the art tend to limit the processing temperature below 200° C., and utilize the flexible substrate with a low thermal expansion coefficient. However, it is not easy to find a suitable flexible substrate according to the cost of materials, the light transmittance of the substrate, the collocation of the chemical solutions used in the process, and the processing temperature, etc. Besides, skilled artisans in the art have already proposed a thin film transistor with a special layout to enhance the manufacturing yield. The special layout will be described in detail with reference to FIG. 2.

FIG. 2A is a schematic view of the layout of another conventional thin film transistor. Referring to 2A, a thin film transistor 200 is fabricated on a flexible substrate (not shown), and the thin film transistor 200 includes a gate 202, a gate insulating layer 204, a channel layer 206, a source 208, and a drain 210. The gate 202 is disposed on the substrate, and the gate insulating layer 204 is disposed over the substrate for covering the gate 202. The channel layer 206 is located above the gate. In other words, the gate insulating layer 204 is located between the gate 202 and the channel layer 206. Further, the source 208 and the drain 210 are disposed on a portion of the gate insulating layer 204 and cover a portion of the channel layer 206.

As shown in FIG. 2A, when misalignment occurs between the gate 202 and the source 208 and the drain 210, the source 208 and the drain 210 may still cover a portion of the channel layer 206. That is, the film transistor 200 can operate normally. Compared with the thin film transistor 100 shown in FIG. 1, the misalignment tolerance of the layout of the gate 202 and the channel layer 206 in the X-axis direction is relatively preferable, and the misalignment tolerance of the layout of the source 208 and the drain 210 in the Y-axis direction is also relatively preferable. Therefore, the manufacturing yield of the thin film transistor 200 is higher than that of the thin film transistor 100.

FIG. 2B is a schematic view of a thin film transistor, when misalignment in the Y-axis direction occurs for the gate and the channel layer of the thin film transistor. Referring to FIG. 2B, when misalignment in the Y-axis direction occurs to the gate 202 and the channel layer 206, the thin film transistor 200 possibly cannot operate normally. The main reason is that the misalignment between the gate 202 and the channel layer 206 is not considered when the layout of the thin film transistor 200 was proposed, such that the misalignment tolerance of the gate 202 and the channel layer 206 in the Y-axis direction is apparently insufficient. Therefore, further improvements are required.

### SUMMARY OF THE INVENTION

Accordingly, the present invention is directed to provide a thin film transistor with a high tolerance for misalignments between different layers of thin films. Even if misalignment occurs between the different layers of thin films, the thin film transistor can still operate normally.

As embodied and broadly described herein, the present invention provides a thin film transistor suitable for being disposed over a flexible substrate. The thin film transistor of the present invention includes a gate, a gate insulating layer, a channel layer, a first conductive pattern, and a second conductive pattern. The gate is disposed on the flexible substrate, and the gate insulating layer is disposed over the flexible substrate for covering the gate. The channel layer is disposed on the gate insulating layer and located above the gate. The channel layer has at least one first contact region and multiple second contact regions, and the first contact region is located between the second contact regions. In addition, the first conductive pattern is disposed on a portion of the gate insulating layer and the first contact region of the channel layer; the second conductive pattern is disposed on a portion of the gate insulating layer and the second contact region of the channel layer; and the first conductive pattern is electrically insulated from the second conductive pattern.

In one embodiment of the present invention, the number of the first contact regions can be 1, and the number of the second contact regions can be 2. Moreover, the first contact region is, for example, located at the middle of the channel layer, and the second contact regions are, for example, respectively located at both sides of the first contact region.

In one embodiment of the present invention, the material of the above channel layer is amorphous silicon or micro-crystalline silicon.

In one embodiment of the present invention, the above first conductive pattern includes a drain covering the first contact region, and the second conductive pattern includes multiple sources covering the second contact region, and a data line connected to the sources. Moreover, the extending direction of the sources and the drain is, for example, in parallel with or perpendicular to that of the data line.

In one embodiment of the present invention, the above first conductive pattern includes a drain covering the first contact region, and the second conductive pattern includes a source and a data line connected to the source, wherein the source and the data line cover the second contact region. Moreover, the extending direction of the source and the drain is, for example, in parallel with or perpendicular to that of the data line.

In one embodiment of the present invention, the above second conductive pattern includes multiple drains covering the second contact region, and the first conductive pattern includes a source covering the first contact region, and a data line connected to the source. Moreover, the extending direction of the source and the drains is, for example, in parallel with or perpendicular to that of the data line.

Since the thin film transistor of the present invention utilizes the architecture with double sources or double drains, when misalignment occur between the thin films, the thin film transistor of the present invention can still operate normally, as long as the misalignment is not too severe. Therefore, the thin film transistor of the present invention can overcome the problem of misalignment resulting from the flexible substrate. Moreover, the manufacturing of the thin film transistor of the present invention is compatible with the current process, and the manufacturing yield can be significantly increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of the layout of a conventional thin film transistor.

FIG. 2A is a schematic view of the layout of another conventional thin film transistor.

FIG. 2B is a schematic view of a thin film transistor, when misalignments in the Y-axis direction occur to the gate and the channel layer of the thin film transistor.

FIG. 3A is a schematic view of the layout of a thin film transistor according to a first embodiment of the present invention.

FIG. 3B is a schematic view of a thin film transistor of the first embodiment, when misalignment occurs.

FIG. 4A is a schematic view of the layout of a thin film transistor according to the second embodiment of the present invention.

FIG. 4B is a schematic view of a thin film transistor of the second embodiment, when misalignment occurs.

FIG. 5A is a schematic view of the layout of a thin film transistor according to the third embodiment of the present invention.

FIG. 5B is a schematic view of the thin film transistor of the third embodiment, when misalignment occurs.

FIG. 6A is a schematic view of the layout of a thin film transistor according to a fourth embodiment of the present invention.

FIG. 6B is a schematic view of the thin film transistor of the fourth embodiment, when misalignment occurs.

FIG. 7A is a schematic view of the layout of a thin film transistor according to a fifth embodiment of the present invention.

FIG. 7B is a schematic view of the thin film transistor of the fifth embodiment, when misalignment occurs.

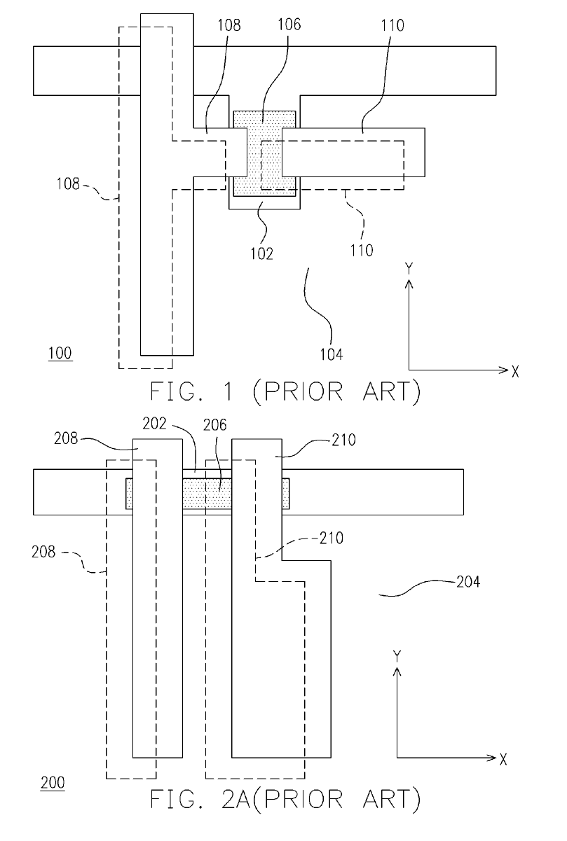

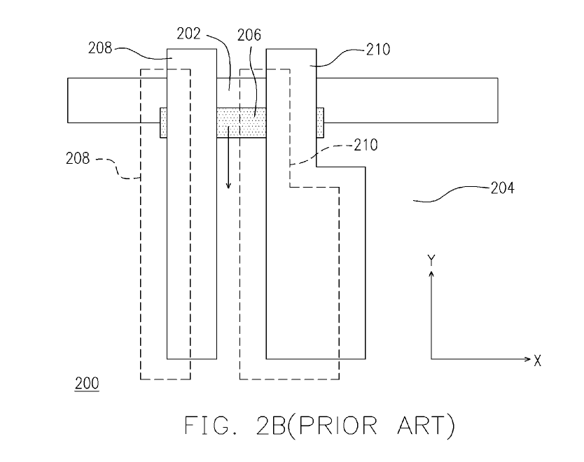

### DESCRIPTION OF EMBODIMENTS

### The First Embodiment

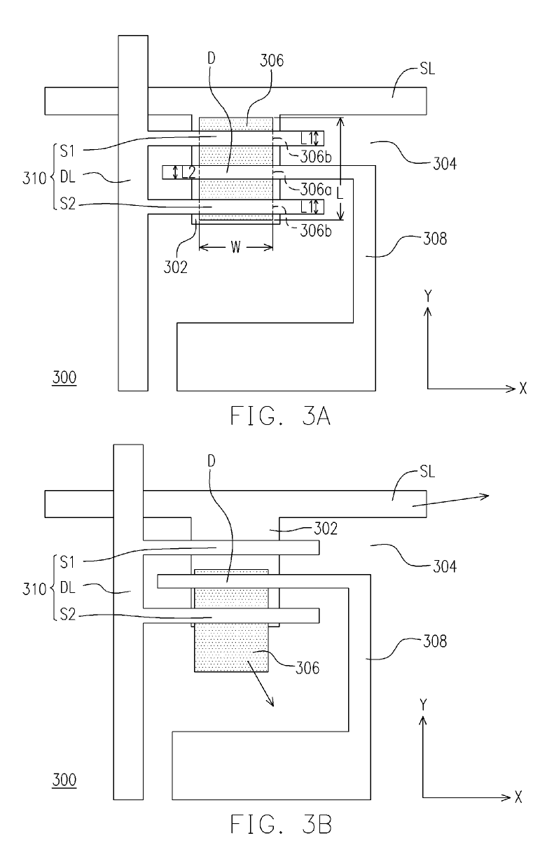

FIG. 3A is a schematic view of the layout of a thin film transistor according to a first embodiment of the present invention. Referring to FIG. 3A, a thin film transistor 300 of the present invention is suitable for being disposed on a flexible substrate (not shown). The thin film transistor 300 includes a gate 302, a gate insulating layer 304, a channel layer 306, a first conductive pattern 308, and a second conductive pattern 310. The gate 302 is disposed on the flexible substrate and the gate insulating layer 304 is disposed on the flexible substrate for covering the gate 302. The channel layer 306 is disposed on the gate insulating layer 304 and above the gate 302. The channel layer 306 has at least one first contact region 306a and multiple second contact regions 306b, and the first contact region 306a is located between the second contact regions 306b. In addition, the first conductive pattern 308 is disposed on a portion of the gate insulating layer 304 and the first contact region 306a of the channel layer 306, the second conductive pattern 310 is disposed on a portion of the gate insulating layer 304 and the second contact region 306b of the channel layer 306, and the first conductive pattern 308 is electrically insulated from the second conductive pattern 310.

Generally, the gate 302 of the thin film transistor 300 can be connected to a scan line SL, and the gate 302 usually protrudes from one side of the scan line SL (as shown in FIG. 3). However, the present invention does not limit the configuration of the gate 302 and the scan line SL. In other words, the gate 302 of the present invention also protrudes respectively from both sides of the scan line SL, or is integrated directly in the scan line SL without protruding therefrom. As for the configuration of the gate 302, it depends on the requirements of the manufacturers.

In the present invention, the gate insulating layer 304 can be a silicon oxide layer, a silicon nitride layer, a silicon oxy-nitride layer, and the like. Of course, the gate insulating layer 304 also can be a composite insulating layer formed by dielectric layers with different materials.

In the present embodiment, the first conductive pattern 308 includes a drain D covering the first contact region 306a, and the second conductive pattern 310 includes multiple sources S1, S2 covering the second contact region 306b, and a data line DL connected to the sources S1, S2. It is clear in FIG. 3 that the extending direction of the sources S1, S2 and the drain D of the present embodiment is substantially perpendicular to that of the data line DL. Of course, the present invention does not limit the extending direction of the sources S1, S2 and the drain D must be perpendicular to that of the data line DL.

Referring to FIG. 3A, the channel layer 306 of the present embodiment is for example an amorphous silicon pattern or a micro-crystalline silicon pattern with a rectangle shape, and the length and the width of the channel layer 306 are respectively L and W. It should be noted that the first contact region 306a in the channel layer refers to the amorphous silicon layer or the micro-crystalline silicon layer under the sources S1, S2. The size of the first contact region 306a depends on the line width L1 of the sources S1, S2 and the width W of the channel layer. Further, the second contact region 306b in the channel layer 306 refers to the amorphous silicon layer or the micro-crystalline silicon layer under the drain D. The size of the second contact region 306b depends on the line width L2 of the drain D and the width W of the channel layer. In other words, the distributing position and the number of first contact regions 306a depends on the position and the number of drains D, and the distributing position and the number of second contact regions 306b depends on the position and the number of sources S1, S2. In particular, the number of first contact regions 306a is 1, and the number of second contact regions 306b is 2. The first contact region 306a is located at the middle of the channel layer 306, and the second contact regions 306 are located respectively at both sides of the first contact region 306a.

FIG. 3B is a schematic view of a thin film transistor of the first embodiment, when misalignment occurs. Referring to FIG. 3B, when fabricating the thin film transistor 300 on the flexible substrate, among the gate 302, the channel layer 306, the first conductive pattern 308, and the second conductive pattern 310, misalignments often occur because of the expansion and the shrink of the flexible substrate resulted from temperature change. The misalignment often includes the offsets in X-axis direction and Y-axis direction. Taking FIG. 3B as an example, because of the misalignment, the source S1 cannot contact with the channel layer 306, and therefore the channel layer 306 between the source S1 and the drain D cannot function normally. At this time, the channel layer 306 between the source S2 and the drain D can still function normally.

To sum up, the thin film transistor 300 of the present embodiment can operate normally when misalignments occur. Therefore, the process window of the thin film transistor 300 of the present embodiment will be greatly widened during manufacturing. Thereby, the process yield will be increased, and the process cost will be reduced.

### The Second Embodiment

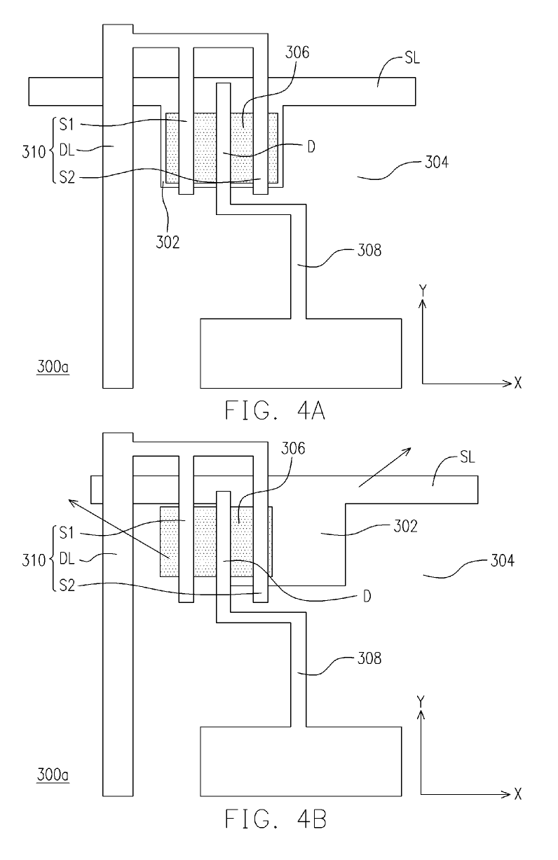

FIG. 4A is a schematic view of the layout of a thin film transistor according to the second embodiment of the present invention. Referring to FIG. 4, a thin film transistor 300a of the present embodiment is similar to the thin film transistor 300 of the first embodiment. They are both the thin film transistor with dual source architecture. The mainly difference is that the extending direction of the source S1, source S2 and drain D. In particular, in the thin film transistor 300a of the present embodiment, the extending direction of the source S1, source S2 and drain D is in parallel with that of the data line DL.

FIG. 4B is a schematic view of a thin film transistor of the second embodiment, when misalignment occurs. Referring to FIG. 4B, when misalignments occur among the gate 302, the channel layer 306, the first conductive pattern 308, and the second conductive pattern 310 because of the expansion and the shrink of the flexible substrate resulted from temperature change, the channel layer 306 between the source S1 and the drain D cannot function normally. The main reason is that this portion of the channel layer 306 cannot appear in the ON state under the control of the gate 302. At this time, the channel layer 306 between the source S2 and the drain D can still be controlled by the gate 302, so as to function normally.

### The Third Embodiment

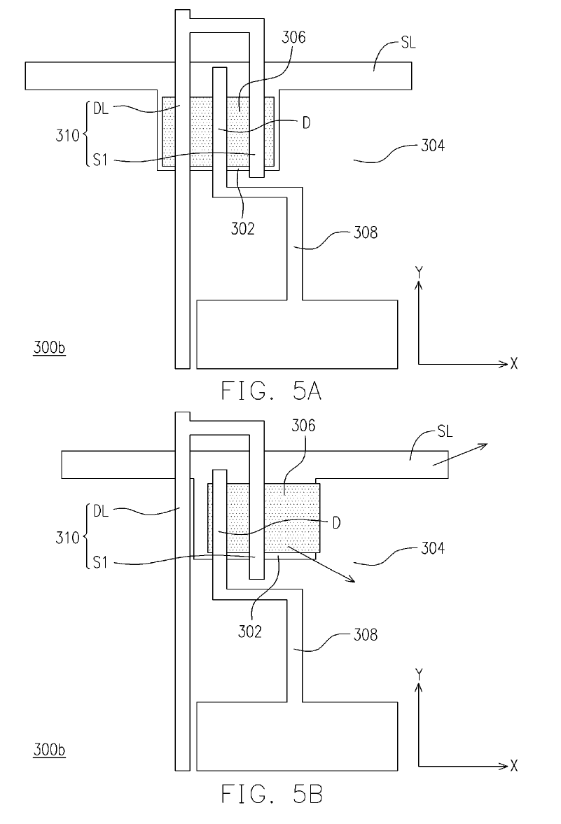

FIG. 5A is a schematic view of the layout of a thin film transistor according to the third embodiment of the present invention. Referring to FIG. 5A, the thin film transistor 300b of the present embodiment is similar to the thin film transistor 300a of the second embodiment. The mainly difference is that the thin film transistor 300b of the present embodiment does not have the source S1, and only the source S2 and the data line DL are included. In particular, in the thin film transistor 300b of the present embodiment, the second conductive pattern 310 includes a source S2 and a data line DL connected to the source S2. The source S2 and the data line DL respectively cover the corresponding second contact regions 306b.

In the present embodiment, the extending direction of the source S2 and the drain D is parallel to that of the data line DL. In addition, the distributing position and the number of second contact regions 306b of the present embodiment depends on the position and the number of the source S2 and the data line DL, instead of the position and the number of the sources S1, S2 (the second embodiment).

FIG. 5B is a schematic view of a thin film transistor of the third embodiment, when misalignment occurs. Referring to FIG. 5B, when misalignment occurs among the gate 302, the channel layer 306, the first conductive pattern 308, and the second conductive pattern 310 because of the expansion and the shrink of the flexible substrate resulted from temperature change, the data line DL cannot contact with the channel layer 306, so the channel layer 306 between the data line DL and the drain D cannot function normally. At this time, the channel layer 306 between the source S2 and the drain D can still be controlled by the gate 302, so as to function normally.

### The Fourth Embodiment

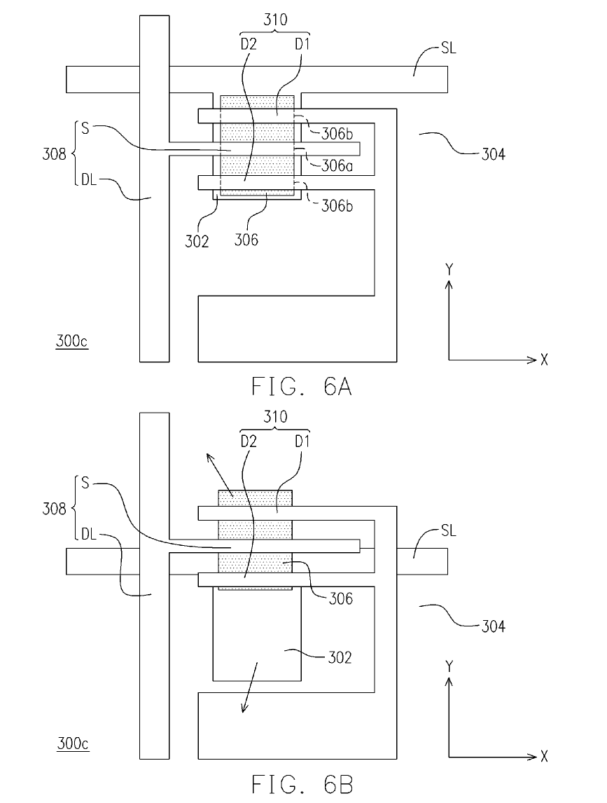

FIG. 6A is a schematic view of the layout of a thin film transistor according to the fourth embodiment of the present invention. Referring to FIG. 6A, the thin film transistor 300c of the present embodiment is similar to the thin film transistor 200 of the first embodiment. The mainly difference is that the design of the first conductive pattern 308 and the second conductive pattern 310. In particular, the first conductive pattern 308 of the present embodiment includes a source S covering the first contact region 306a and a data line DL connected to the source S. And the second conductive pattern 310 includes multiple drains D1, D2 covering the second contact regions 306b. It should be noted that the extending direction of the source S and the drains D1, D2 of the present embodiment is perpendicular to that of the data line DL. Of course, the present invention is not limited to that the extending direction of the source S and the drains D1, D2 of the present embodiment is perpendicular to that of the data line DL.

FIG. 6B is a schematic view of a thin film transistor of the fourth embodiment, when misalignment occurs. Referring to FIG. 6B, when misalignment occurs among the gate 302, the channel layer 306, the first conductive pattern 308, and the second conductive pattern 310 because of the expansion and the shrink of the flexible substrate, the channel layer 306 between the source S and the drain D cannot function normally. The main reason is that this portion of the channel layer 306 cannot appear in the ON state under the control of the gate 302. At this time, the channel layer 306 between the source S and the drain D2 can still be controlled by the gate 302, so as to function normally.

### The Fifth Embodiment

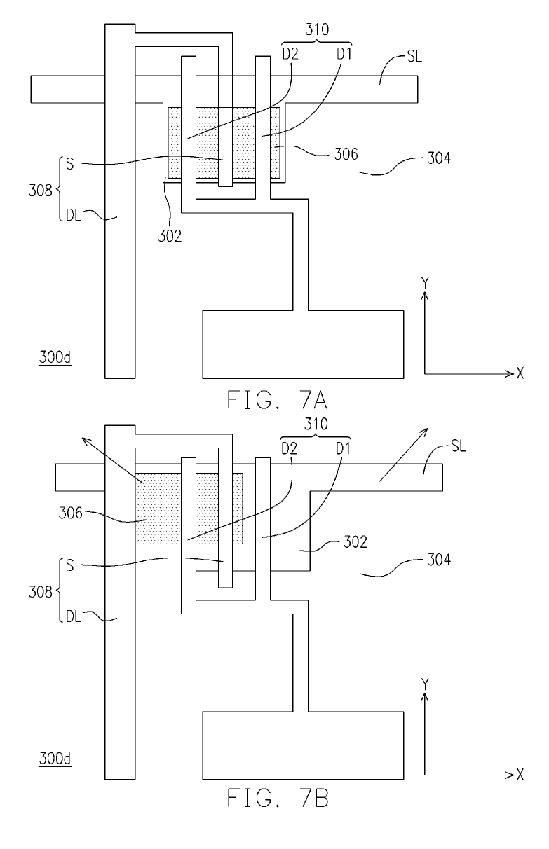

FIG. 7A is a schematic view of the layout of a thin film transistor according to a fifth embodiment of the present invention. Referring to FIG. 7A, the thin film transistor 300dof the present embodiment is similar to the thin film transistor 300c of the fourth embodiment. They are both the thin film transistor with dual drain architecture. The mainly difference is that the extending direction of the source S, drain D1 and drain D2. In particular, in the thin film transistor 300d of the present embodiment, the extending direction of the source S, drain D1, and drain D2 is in parallel with that of the data line DL.

FIG. 7B is a schematic view of a thin film transistor of the fifth embodiment, when misalignment occurs. Referring to FIG. 7B, when misalignment occurs among the gate 302, the channel layer 306, the first conductive pattern 308 and the second conductive pattern 310 because of the expansion and the shrink of the flexible substrate resulted from temperature change, the drain D cannot contact with the channel layer 306, so the channel layer 306 between the source S and the drain D1 cannot function normally. At this time, the channel layer 306 between the source S and the drain D2 can still be controlled by the gate 302, so as to function normally.

To sum up, the thin film transistor of the present invention at least has the following advantages:

The thin film of the present invention adopts the architecture of dual source or dual drain, so when misalignment occurs between the films, if the misalignment is not too serious, less then ⅓ of the pixel width, the thin film transistor of the present invention can still operate normally.

The manufacturing of the thin film transistor of the present invention is compatible with the current process, so it is not necessary to modify the process greatly and the manufacturing yield can be enhanced greatly.

The manufacturing cost of the thin film transistor of the present invention can be reduced significantly.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A thin film transistor suitable for being disposed over a flexible substrate, comprising:
a gate, disposed on the flexible substrate;
a gate insulating layer, disposed over the flexible substrate for covering the gate;
a channel layer, disposed on the gate insulating layer, wherein the channel layer is located above the gate, the channel layer has at least one first contact region and a plurality of second contact regions, and the first contact region is located between the second contact regions;
a first conductive pattern, disposed on a portion of the gate insulating layer and the first contact region of the channel layer; and
a second conductive pattern, disposed on a portion of the gate insulating layer and the second contact region of the channel layer, wherein the first conductive pattern is electrically insulated from the second conductive pattern.

2. The thin film transistor as claimed in claim 1, wherein the number of the first contact regions is 1, and the number of the second contact regions is 2.

3. The thin film transistor as claimed in claim 2, wherein the first contact region is located at the middle of the channel layer, and the second contact regions are respectively located at both sides of the first contact region.

4. The thin film transistor as claimed in claim 1, wherein a material of the channel layer is amorphous silicon.

5. The thin film transistor as claimed in claim 1, wherein a material of the channel layer is micro-crystalline silicon.

6. The thin film transistor as claimed in claim 1, wherein the first conductive pattern comprises a drain covering the first contact region, and the second conductive pattern comprises:
a plurality of sources covering the second contact regions; and
a data line connected to the sources.

7. The thin film transistor as claimed in claim 6, wherein the extending direction of the sources and the drain is in parallel with that of the data line.

8. The thin film transistor as claimed in claim 6, wherein the extending direction of the sources and the drain is perpendicular to that of the data line.

9. The thin film transistor as claimed in claim 1, wherein the first conductive pattern comprises a drain covering the first contact region, and the second conductive pattern comprises:
a source; and
a data line connected to the source, wherein the source and the data line cover the second contact region.

10. The thin film transistor as claimed in claim 9, wherein the extending direction of the source and the drain is in parallel with that of the data line.

11. The thin film transistor as claimed in claim 1, wherein the second conductive pattern comprises a plurality of drains covering the second contact regions, and the first conductive pattern comprises:
a source covering the first contact region; and
a data line connected to the source.

12. The thin film transistor as claimed in claim 11, wherein the extending direction of the source and the drains is in parallel with that of the data line.

13. The thin film transistor as claimed in claim 11, wherein the extending direction of the source and the drains is perpendicular to that of the data line.
